(19) United States
(12) Patent Application Publication
(10) Pub. No.: US 2007/0286979 A1
(43) Pub. Date: Dec. 13, 2007

(54) Surface treatment device for optical discs

(76) Inventor: Mao-Sang Lin, Taipei County (TW)

Correspondence Address: BIRCH STEWART KOLASCH & BIRCH, PO BOX 747, FALLS CHURCH, VA, 22040-0747, US

(21) Appl. No.: 11/450,420

(22) Filed: Jun. 12, 2006

(51) Int. Cl. C23C 16/52; B32B 3/02

(52) U.S. Cl. 428/64.1; 427/8

(57) ABSTRACT

A surface treatment device for optical discs comprises a base; and an upper cover, pivotedly coupled to the base, and cooperating with the base to form a gripping space where the optical disc is gripped. The base has a rotary axle in the gripping space for accommodating the central hole of the optical disc and has a grinding element contacting the surface of the optical disc. The upper cover has a connection element, which is able to engage with the rotary axle and is pivotedly coupled to a crank that can be shifted between a folding position and a rotation position. When the crank is shifted to the rotation position, the connection element is engaged with the rotary axle, and the optical disc is gripped fixedly. When rotating the crank, the optical disc will be driven to rotate; thereby, the surface of the optical disc can be cleaned or destroyed.

### FIELD OF THE INVENTION

The present invention relates to a device for treating optical discs, particularly to a surface treatment device for optical discs, which can destroy/enhance the read/write function of an optical disc.

### BACKGROUND OF THE INVENTION

Optical discs, including: CD-R (Compact Disc-Recordable), CD-RW (Compact Disc-ReWritable) and DVD (Digital Video Disc), are high-capacity and easy-to-read memories. Owing to the maturity of the fabrication technology, optical discs have been extensively used in the fields of digital data storage, entertainment, etc., and consumers can buy them conveniently and use them easily. The cleanness of the read/write surface of an optical disc is critical for reading/writing the optical disc. Thus, the tool for cleaning the read/write surfaces of optical discs is very important in maintaining the read/write capability of the optical discs.

Currently, there have been several patents about repairing the read/write surfaces of optical discs. For example, the inventor of the present invention proposed an optical disc repairing mechanism in R.O.C patent publication No.572318, wherein the optical disc repairing mechanism is disposed on a table and used to clean, maintain and repair optical discs. The abovementioned mechanism comprises: a transmission part; a connection part, disposed on the transmission part; an elastic element, disposed between the transmission part and the connection part; a carry part, disposed on the connection part; and a repairing part, disposed on the carry part. The optical disc is disposed on the repairing mechanism, and the rotating repairing mechanism drives the optical disc to rotate so that the optical disc can be grounded. Thereby, the abrasion on the optical disc is eliminated, and the surface of the optical disc is resumed to a mint one. Thus, the reflection of the laser light is no more influenced by the scratches on the surface of the optical disc, and the digital data inside the optical disc is restored. However, such a mechanism is somewhat complicated because of the transmission structure for driving the optical disc.

The inventor of the present invention also proposed an optical disc repairing machine in R.O.C patent publication No.467351, which is used to clean, maintain and repair optical discs. In the operation of this conventional device, a scratched optical disc is placed on a disc holder; next, a grinding wheel is installed to a grinding arm; next, a grinding agent is applied onto the grinding wheel; next, the grinding wheel is placed on the optical disc; next, power is turned on to drive the disc holder to rotate; and thus, the grinding wheel is also driven to rotate and perform the grinding operation. In this conventional technology, both the grinding wheels and the grinding agents are classified into three grades: Coarse, Medium and Fine, and the finest grade thereof is used to polish the optical disc. Via the multi-stage grindings, the scratches of the optical disc is ground and polished to restore the scratched surface to be a fresh one. Such a machine is electrically driven and suitable to process a large quantity of optical discs.

Besides, R.O.C patent publication No.239587 also proposed an optical disc cleaning device, which comprises: a base, carrying an optical disc; and an upper cover, disposed corresponding to the base with a portion of the edge of the upper cover pivotedly connected with a portion of the edge of the base. Thus, the upper cover can be lifted and closed to expose and cover the interior of the base. A cleaning part is installed to the base-confronting internal surface of the upper cover, and the cleaning part spins and simultaneously revolves with respect to the central axis of the disc holder. It can be known from those described above: the base needs a considerable room to contain the optical disc, and the planetary rotation of the cleaning part needs a complicated mechanism.

A complicated mechanism is hard to maintain, and the maintenance thereof is expensive. For a user who intends to repair only a small quantity of optical discs, what he looks forward to is exactly a simple mechanism and a compact size of an optical disc repairing device. Therefore, the present invention proposes a surface treatment device for optical discs, which is advantaged in a simple mechanism, better space efficiency and easy operation. Hereinafter, the present invention is to be disclosed.

### SUMMARY OF THE INVENTION

The primary objective of the present invention is to solve the abovementioned problems. The present invention is a surface treatment device for optical discs, which comprises a base; and an upper cover, pivotedly coupled to the base, and cooperating with the base to form a gripping space where the optical disc is gripped. The base has a rotary axle in the gripping space for disposing the optical disc and has a grinding element contacting the surface of the optical disc. The upper cover has a connection element, which is able to engage with the rotary axle and is pivotedly coupled to a crank that can be shifted between a folding position and a rotation position. When the crank is shifted to the rotation position, the connection element is engaged with the rotary axle, and the optical disc is gripped fixedly. When the user rotates the crank, the optical disc will be driven to rotate; thereby, the surface of the optical disc can be cleaned or destroyed. As described above, the surface treatment device of the present invention is advantaged in simple structure and space efficiency.

Another objective of the present invention is to destroy, clean or repair an optical disc so as to destroy the data stored in the optical disc or enhance the read/write capability of the optical disc, wherein the surface characteristic of the grinding element is selected according to the operational objective. When the user intends to destroy the optical disc, a rough surface is selected to roughly abrade the printed surface of the optical disc. When the user intends to clean or repair the optical disc, a soft surface is selected to clean or repair the transparent protection layer.

### BRIEF DESCRIPTION OF THE DRAWINGS

FIG. 1 is a perspective view schematically showing the appearance of the present invention.

FIG. 2 is an exploded view schematically showing the structure of the present invention.

FIG. 3A and FIG. 3B are sectional views schematically showing the operation of the present invention.

FIG. 4A and FIG. 4B are diagrams schematically showing the operation of a portion of parts of the present invention.

FIG. 5 is a diagram schematically showing the operation of the entire device of the present invention.

FIG. 6 is an exploded view schematically showing one embodiment of the present invention.

### DETAILED DESCRIPTION OF THE PREFERRED EMBODIMENTS

Below, the detailed description and technical contents of the present invention are to be stated in cooperation with the attached drawings.

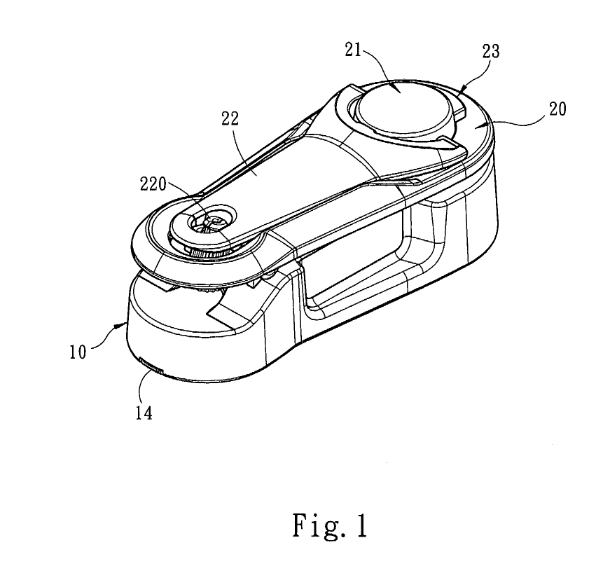

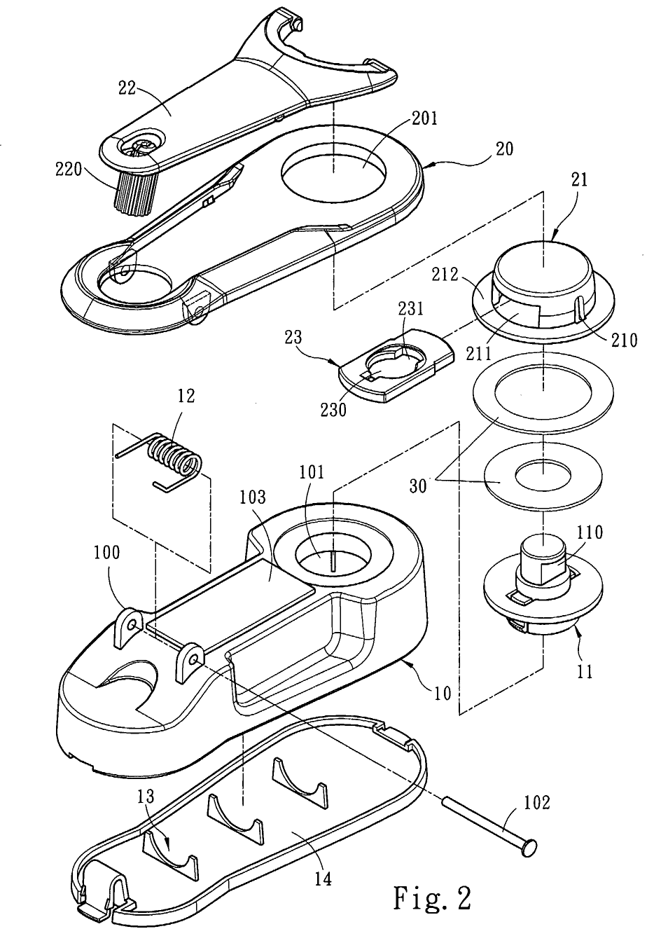

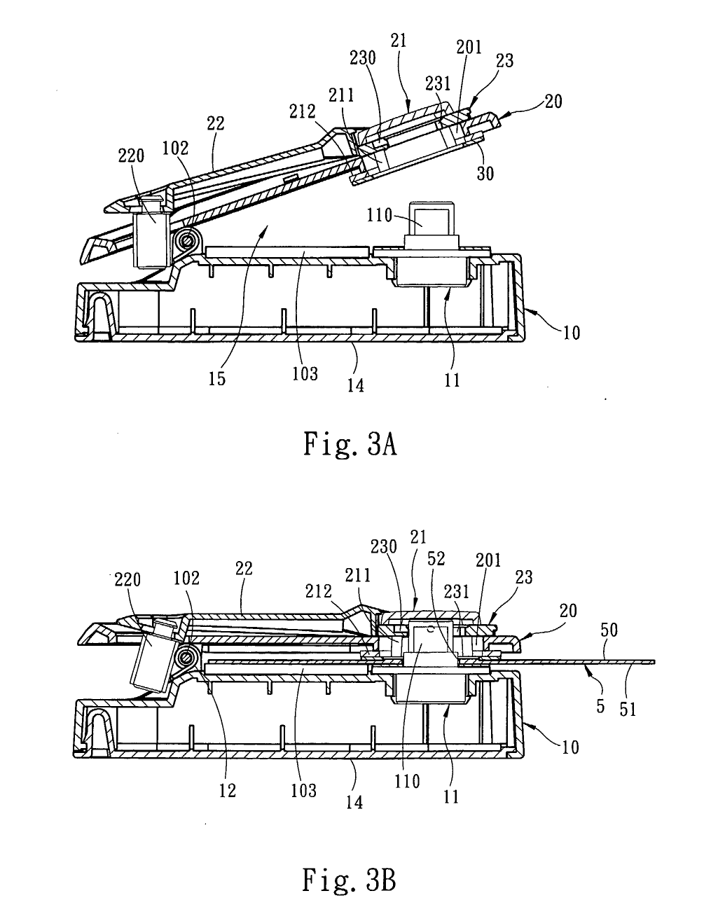

Refer to FIG. 1, FIG. 2, FIG. 3A, and FIG. 3B, which are respectively a perspective view, an exploded view and sectional views schematically showing the appearance, the structure and the operation of the present invention. The present invention is a surface treatment device for optical discs, which is used to destroy or enhance the read and write function of an optical disc 5 (shown in FIG. 3B). Different surface treatments can disable or enhance the read and write capability of the optical disc 5 so that the data stored in the optical disc 5 will be destroyed or protected. The surface treatment device for optical discs of the present invention has a base 10, and one side of the base 10 has a pivotal element 100, and a pin 102 can be inserted through the pivotal element 100 to pivotedly interconnect the base 10 and an upper cover 20 so that the upper cover 20 may be opened or closed. A gripping space 15 is formed between the base 10 and the upper cover 20, and one side of the optical disc 5 is gripped in the gripping space 15. Opposite to the pivotal element 100 and across the gripping space 15, an accommodation hole 101 is formed on the other side of the base 10 to accommodate a rotary axle 11 that can penetrate the central hole 52 of the optical disc 5 to install the optical disc. A gripping plate 30 is disposed in the rotary axle 11 and faces one surface of the optical disc 5. A grinding element 103 is installed on the base 10 and disposed between the pivotal element 100 and the rotary axle 11. The grinding element 103 may be a rough surface used to roughly abrade the printed surface 50 of the optical disc 5, or a soft surface used to clean or repair the protection layer 51 of the optical disc 5. The type of the grinding element 103 is selected according to the aim of the surface treatment. The rough surface can roughly abrade the printed surface 50 and destroy the stored data; the soft surface can refine the protection layer 51 of the optical disc 5 and benefit the read and write operation of an optical disc drive.

An installation hole 201 is formed in the upper cover 20 and disposed corresponding to the rotary axle 11, and a connection element 21 is inserted through the installation hole 201. A position-limiting flange 212 protrudes from the connection element 21 and is disposed on the position where the gripping space 15 is formed. A through hole 211 is installed in the connection element 21 along the radial direction of the connection element 21. One gripping plate 30 is disposed on one side of the position-limiting flange 212 and cooperates with the other gripping plate 30 to grip the optical disc 5. A slide block 23 is installed inside the through hole 211 and is kept inside the through hole 211 by the position-limiting flange 212. The slide block 23 has a fitting hole 230, and the fitting hole 23 has a fitting slot 231. The rotary axle 11 has a fitting portion 110, which has a shape matching the fitting slot 231 and cooperates with the fitting slot 231 to perform movement transmission. One side of the connection element 21 (near the gripping space 15) has two pivotal holes 210 used to pivotedly connect the connection element 21 with a crank 22. The crank 22 can be accommodated on an accommodation portion on the upper cover 20 and can be rotated pivotedly to a rotation position. One end of the crank 22 (opposite to the end pivotedly connected with the connection element 21) has a rotary knob 220 for the holding of the user's hand; thereby, the user can rotate the crank 22 with his hand.

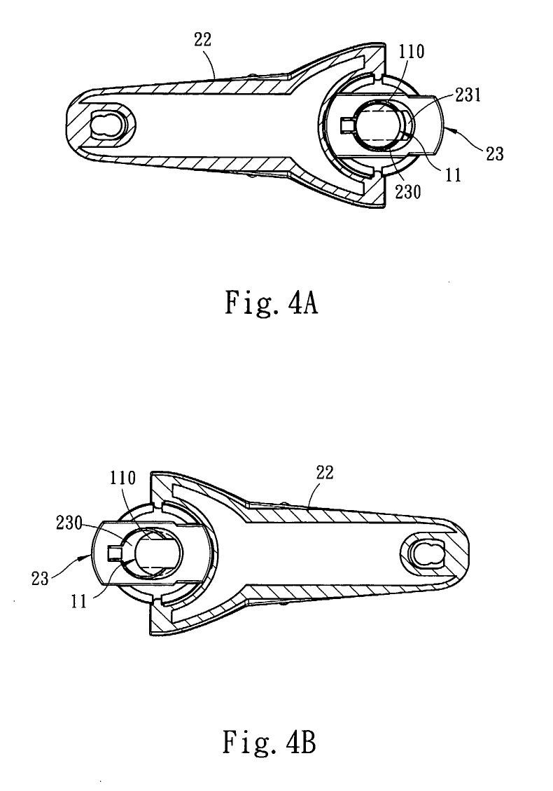

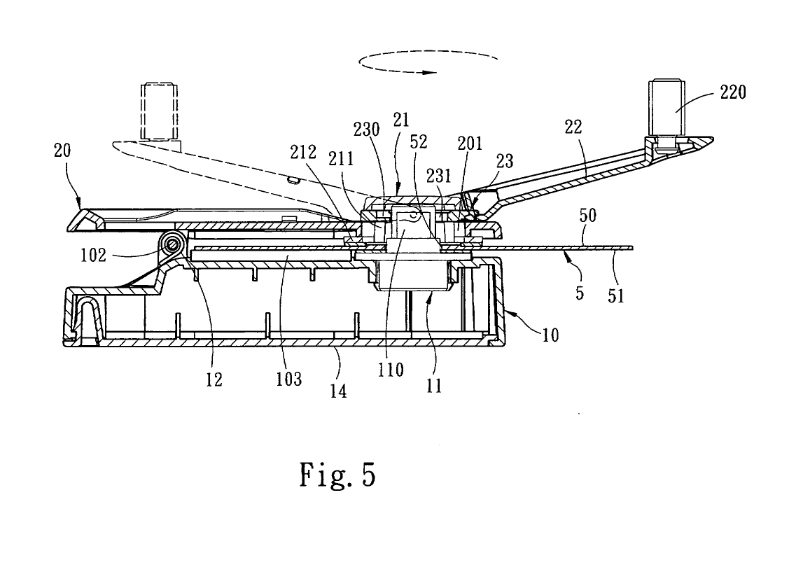

Refer to FIG. 4A, FIG. 4B and FIG. 5 diagrams respectively showing the operations of a portion of parts and the entire device of the present invention schematically. An elastic element 12 is installed in the pivotal connection portion of the base 10 and the upper cover 20 so that the base 10 and the upper cover 20 are normally kept in gripping state. When the optical disc 5 are mounted on the rotary axle 11 with the rotary axle penetrating the central hole 52 of the optical 5, the gripping plates 30 of the rotary axle 11 and the connection element 21 respectively contact the lower surface and upper surface of the optical disc 5 and cooperate to grip the optical disc 5. When the crank 22 is pivotedly rotated to the rotation position, the slide block 23 will be displaced horizontally so that the fitting slot 231 of the slide block 23 will engage with the fitting portion 110 of the rotary axle 11. Thereby, when the user rotates the crank 22 with the rotary knob 220, the rotary axle 11 is driven to rotate, and the optical disc 5 gripped by the gripping plates 30 is also driven to rotate. When the user intends to destroy the data stored in the optical disc 5, he should select a rough surface as the grinding element 103 so that the grinding element 103 will roughly abrade and destroy the printed surface 50 of the optical disc 5. When the user intends to enhance the read and write capability of the optical disc 5, he should select a soft surface (such as a chamois leather or a soft fabric) as the grinding element 103 so that the dirt on the protection layer 51 of the optical disc 5 can be cleaned.

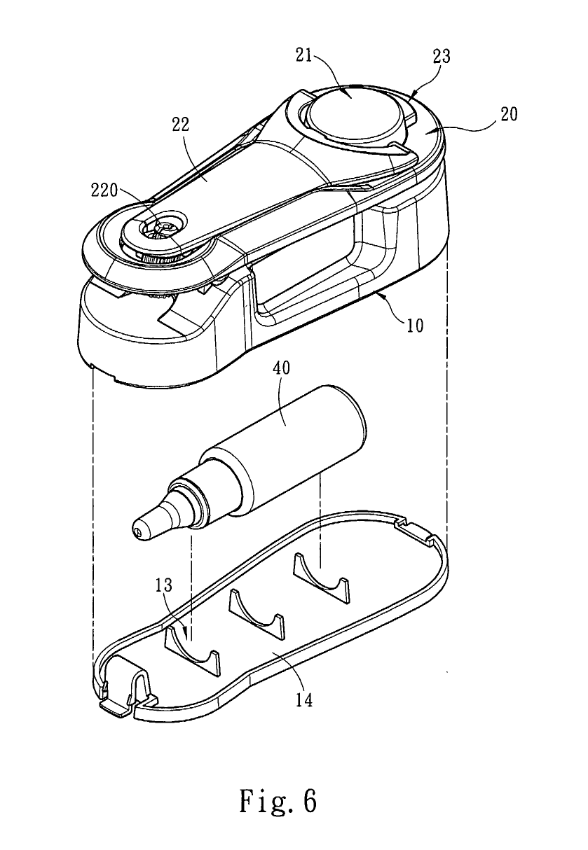

In one embodiment of the present invention, when the protection layer 51 is seriously damaged, a repair liquid is uniformly applied onto the protection 51 to repair the protection layer 51 and improve the read and write capability of the optical disc 5. Refer to FIG. 6 an exploded view schematically showing one embodiment of the present invention. In this embodiment, the base 10 has a bottom cover 14, and the bottom cover 14 has a concaved region 13 used to accommodate a storage bottle 40 in which the repair liquid is stored. When the optical disc 5 needs repairing, the user takes out the storage bottle 40 and applies the repair liquid onto the soft surface and then utilizes the device of the present invention to uniformly distribute the repair liquid onto the protection layer 51; thereby, the read and write function of the optical disc 5 can be improved.

The present invention does not have to hold the entire optical disc 5 inside the device but only needs to grip one side of the optical disc 5; therefore, the device of the present invention has a smaller size and occupies less space. Further, the surface treatment (rough abrasion, cleaning or repairing) of the printed surface 50 or protection layer 51 of the optical disc 5 can be performed via manually operating the crank 22. Therefore, the device of the present invention has a simpler structure than that of the conventional technology and is very suitable to the users who process only a smaller quantity of optical discs. Accordingly, the present invention possesses the novelty and non-obviousness demanded by the regulation for applying a patent.

Those described above are only the preferred embodiments to clarify the present invention. However, it is not intended to limit the scope of the present invention. Any equivalent modification and variation according to the spirit of the present invention is to be also included within the scope the claims of the present invention stated below.

What is claimed is:

1. A surface treatment device for optical discs, used to grip an optical disc and clean said optical disc during the rotation of said optical disc, and comprising:
a base; and
an upper cover, pivotedly coupled to said base, and cooperating with said base to form a gripping space where said optical disc is gripped, wherein said base has a rotary axle in said gripping space for accommodating the central hole of said optical disc; said base also has a grinding element used to grind the surface of said optical disc; said upper cover has a connection element able to engage with said rotary axle and pivotedly coupled to a crank that can be shifted between a folding position and a rotation position; when said crank is shifted to said rotation position, said connection element is engaged with said rotary axle, and said optical disc is gripped fixedly; and rotating said crank will drive said optical disc to rotate.

2. The surface treatment device for optical discs according to claim 1, wherein two gripping plates are respectively disposed in said connection element and said rotary axle and cooperate to grip said optical disc.

3. The surface treatment device for optical discs according to claim 1, wherein an elastic element is installed between said base and said upper cover so that said base and said upper cover can be normally kept in the gripping state.

4. The surface treatment device for optical discs according to claim 1, wherein said connection element has a slide block; said slide block and said rotary axle respectively have a fitting hole and a fitting portion, and the shape of said fitting hole matches the shape of said fitting portion; when said crank is shifted from said folding position to said rotation position, said slide block is translated to engage said fitting hole with said fitting portion.

5. The surface treatment device for optical discs according to claim 1, wherein the bottom of said base has a concaved region, and a storage bottle for storing a repair liquid is disposed inside said concaved region.

6. The surface treatment device for optical discs according to claim 5, wherein the bottom of said base has a cover for covering said concaved region.

7. The surface treatment device for optical discs according to claim 1, wherein said surface of said optical disc is a printed surface, and said grinding element is a rough surface used to roughly abrade said printed surface.

8. The surface treatment device for optical discs according to claim 1, wherein said surface of said optical disc is a protection layer, and said grinding element is a soft surface.

9. The surface treatment device for optical discs according to claim 1, wherein said crank has a rotary knob for the convenience for rotating said crank.
